(19) United States
(12) Patent Application Publication
(10) Pub. No.: US 2014/0146473 A1
(43) Pub. Date: May 29, 2014

(54) POWER SUPPLY WITH A SHELL

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: LEI LIU, Shenzhen (CN); WEI-DONG CONG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/086,975

(22) Filed: Nov. 22, 2013

(30) Foreign Application Priority Data
Nov. 26, 2012 (CN) 2012104858116

(51) Int. Cl. H05K 7/20

(52) U.S. Cl. CPC H05K 7/20136
USPC 361/695

(57) ABSTRACT

A power supply includes a shell. The shell includes a power module to convert alternating current power into direct current power. The power module includes a control unit. The shell defines a rectangular slot to accommodate either a battery or fans. When the rectangular slot accommodates a battery, the battery is electrically connected to the control unit, and the control unit charges the battery. The battery supplies power for a nonvolatile memory. When the rectangular slot accommodates fans, the fans are electrically connected to the power module.

### BACKGROUND

1. Technical Field

The present disclosure relates to a power supply.

2. Description of Related Art

Nonvolatile memory (NVM) is used in servers. The NVM is connected to an independent power supply. The independent power supply is fixed to a specially designed structure, which occupies space on a motherboard. However, for some high load servers, the motherboard may not have enough space to accommodate structure of the power supply.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is an exploded view of an embodiment of a power supply of the present disclosure.

FIG. 2 is an assembled view of the power supply of FIG. 1 and a battery.

FIG. 3 is an assembled view of the power supply of FIG. 1 and two fans.

FIG. 4 is a block diagram of the battery of FIG. 2 connected to a power module.

FIG. 5 is a block diagram of the fans of FIG. 3 connected to the power module of FIG. 4.

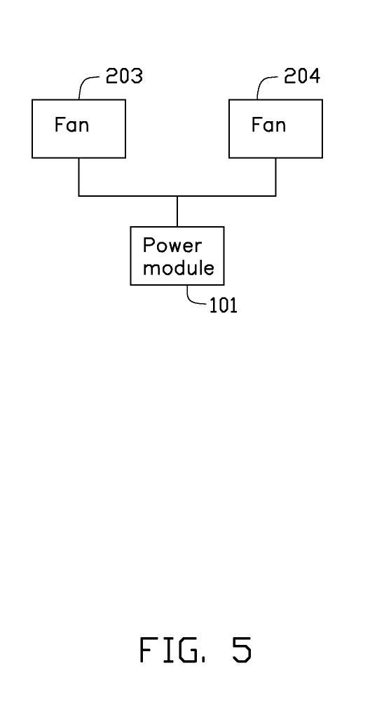

### DETAILED DESCRIPTION

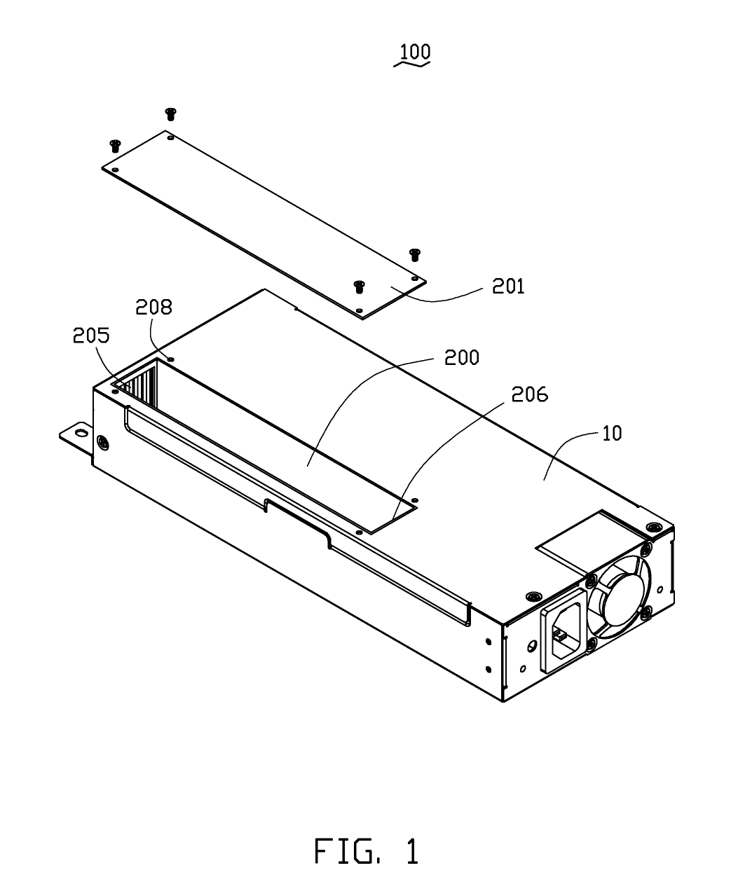

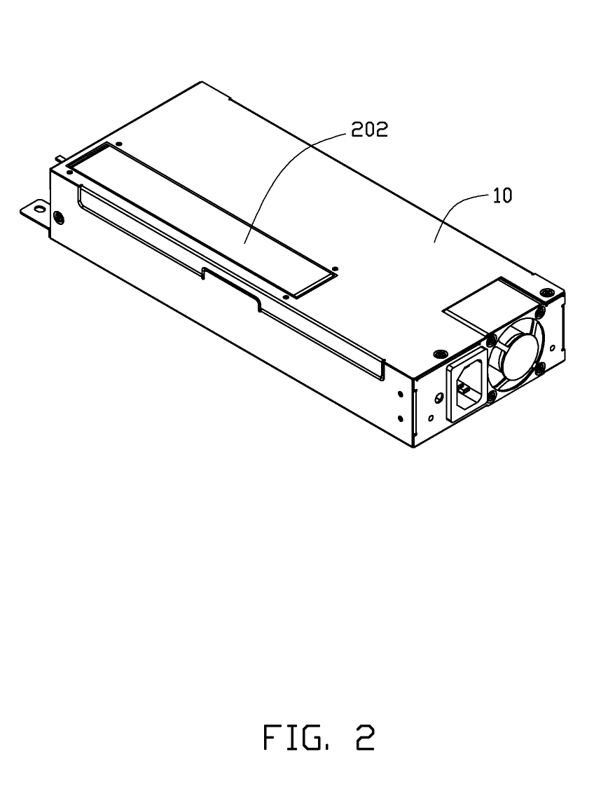

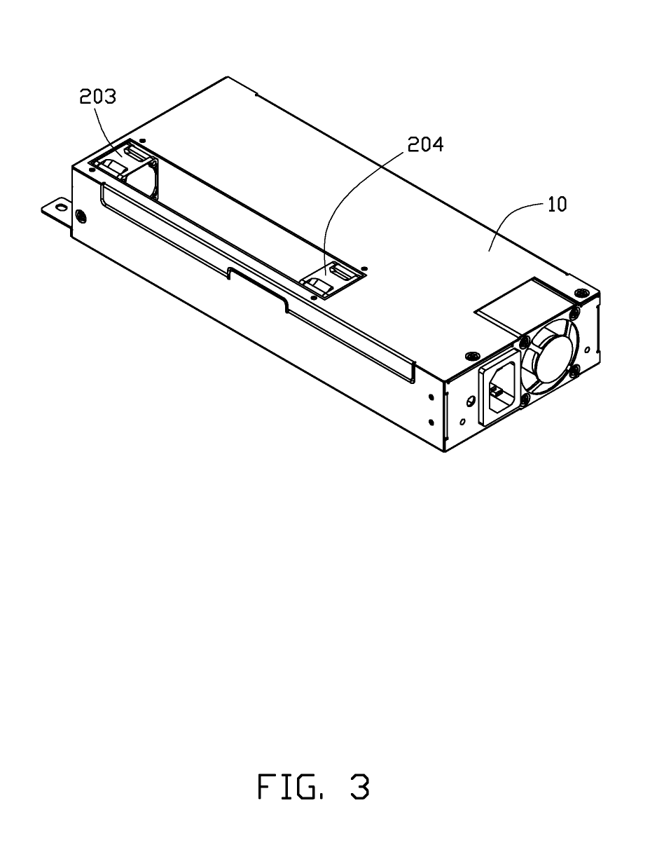

FIGS. 1-3 show an embodiment of a power supply 100.

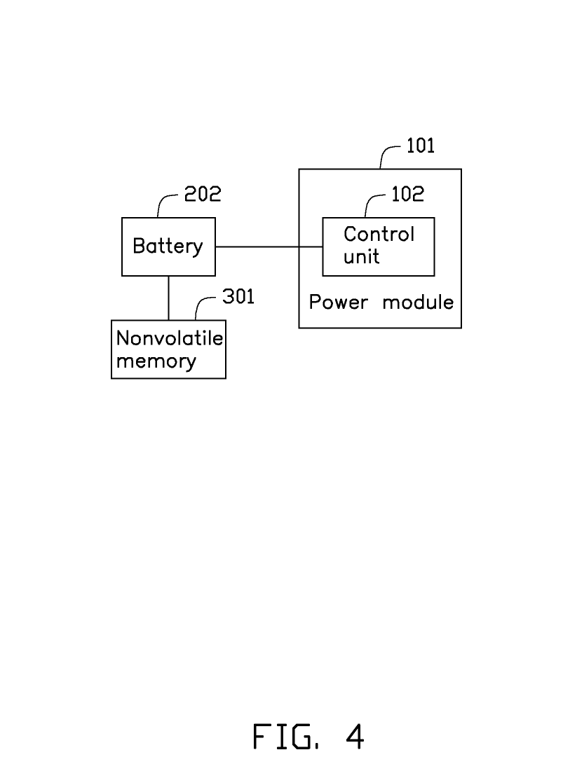

The power supply 100 includes a shell 10 and a power module 101 (shown in FIG. 4). The power module 101 is received in the shell 10. A substantially rectangular slot 200 is defined in the shell 10, and the slot 200 is covered by a cover 201. The shell 10 defines four holes 208 adjacent to four corners of the slot 200. The holes 208 receive screws to fix the cover 201 to the shell 10. Holes 205 are defined in opposite end walls 206 and a bottom wall of the slot 200, to allow an inside of the slot 200 to communicate with an outside of the shell 10.

The slot 200 either receives a battery 202 or two fans 203 and 204. The end walls 206 define holes to fix the fans 203 and 204 in the slot 200. Power lines extend through the holes 205 in the bottom wall of the slot 200 to electrically connect the battery 202 or the fans 203 and 204 to the power module 101. The power module 101 converts an alternating current (AC) power into a direct current (DC) power.

When the fans 203 and 204 are received in the slot 200, the cover 201 is removed from the shell 10. When the battery 202 is received in the slot 200, the cover 201 is fixed to the shell 10 to cover the slot 200.

When the battery 202 is received in the slot 200, a power line extends through the through holes 205 in the bottom wall of the slot 200 to connect the battery 202 to the power module 101. The power module 101 includes a control unit 102 to charge the battery 202. The battery 202 is electrically connected to a nonvolatile memory 301 of a motherboard to supply power to the nonvolatile memory 301.

When the fans 203 and 204 are received in the slot 200, power lines of the fans 203 and 204 extend through the through holes 205 in the bottom wall of the slot 200 to connect the fans 203 and 204 to the power module 101. The fans 203 and 204 are used to cool the power supply 100.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A power supply, comprising:
a shell defining a slot to accommodate either a battery or at least one fan, wherein the shell further comprises a power module received in the shell to convert alternating current power into direct current power, the power module comprising a control unit, opposite end walls of the slot define a plurality of through holes;
a cover detachably mounted to the shell to cover or uncover the slot;
wherein when the slot accommodates the battery, the battery is electrically connected to the control unit and a nonvolatile memory on a motherboard, the control unit charges the battery, the battery supplies power to the nonvolatile memory; and
wherein when the slot accommodates the at least one fan, the fan is electrically connected to the power module.

2. The power supply of claim 1, wherein at least one of the first and second end walls fixes the at least one fan.
